(19) United States
(12) Patent Application Publication
(10) Pub. No.: US 2014/0291006 A1
(43) Pub. Date: Oct. 2, 2014

(54) PRINTED CIRCUIT BOARD SOLDER MOUNTING METHOD AND SOLDER MOUNT STRUCTURE

(71) Applicant: FUJITSU LIMITED, Kawasaki-shi (JP)

(72) Inventors: Keiichi YAMAMOTO, Yokohama (JP); Takahiro KITAGAWA, Kawasaki (JP)

(73) Assignee: FUJITSU LIMITED, Kawasaki-shi (JP)

(21) Appl. No.: 14/147,668

(22) Filed: Jan. 6, 2014

(30) Foreign Application Priority Data
Mar. 28, 2013 (JP) 2013-068964

(51) Int. Cl. H05K 3/36; H05K 1/11

(52) U.S. Cl. CPC H05K 3/363; H05K 1/113
USPC 174/263; 228/256; 228/180.1

(57) ABSTRACT

A printed circuit board solder mounting method of solder-jointing a first-land formed on a first-printed-circuit-board and a second-land formed on a second-printed-circuit-board together, includes: filling a solder-filling-hole with cream solder, the solder-filling-hole provided so as to be open in a planar region of the first-land; arranging a solder-drawing-hole so that the solder-drawing-hole and the solder-filling-hole face each other, the solder-drawing-hole being formed so as to be open in a planar region of the second region, having a center position to be superposed on a center position of the solder-filling-hole, and having a solder wettability higher than a solder wettability of the solder-filling-hole; melting the cream solder in the solder-filling-hole by reflow heating and causing at least part of the cream solder to ascend to the solder-drawing-hole facing the solder-filling-hole; and jointing the first-land and the second-land together by solidifying the cream solder interposed between the first-land and the second-land.

### CROSS-REFERENCE TO RELATED APPLICATION

This application is based upon and claims the benefit of priority of the prior Japanese Patent Application No. 2013-068964, filed on Mar. 28, 2013, the entire contents of which are incorporated herein by reference.

### FIELD

The embodiment discussed herein is related to a printed circuit board solder mounting method and solder mount structure.

### BACKGROUND

With electronic devices becoming more multifunctional, it is often the case that the design of an electronic device is such that a module circuit board, a sub-board, and so on are added in addition to a main board where a CPU and so on are mounted and circuit boards are connected via a flexible printed circuit board (FPC). In the past, a connector is often used for a connection between a rigid printed circuit board (RPC) and a flexible printed circuit board. However, toward the coming of a ubiquitous era, desires for high-density mounting are increasing as electronic devices are becoming further thinner and highly functional. However, there is a limit to making connectors thinner. Moreover, with connectors becoming thinner, operability of coupling a flexible printed circuit board to a connector may be degraded, and a trouble of damaging a connector body and a peripheral component at the time of coupling may be invited. Therefore, it is concerned that product manufacturing efficiency is degraded.

On the other hand, a rigid printed circuit board and a flexible printed circuit board may be directly connected to each other via an anisotropic conducive film (ACF) or anisotropic conductive paste (ACP) in a connectorless manner. ACF (ACP) is a film (paste) where conductive particles are dispersed in a thermosetting resin. By interposing ACF (ACP) between terminals of circuit boards to be connected and facing each other and heating and pressuring the circuit boards, electrical continuity is ensured in a thickness direction and insulation properties are ensured in a plane direction. While this connecting scheme using ACF (ACP) contributes to high-density mounting of circuit boards, a thermocompression process for thermocompressing ACF (ACP) and a device dedicated to thermocompression have to be disadvantageously provided.

Japanese Laid-open Patent Publication No. 9-245856, Japanese Unexamined Utility Model Registration Application Publication No. 63-39969, and Japanese Laid-open Patent Publication No. 63-1094 are examples of related art.

To solve the problems described above, the flexible printed circuit board may be connected to the rigid printed circuit board by a solder joint. In this case, the following problems arise. That is, since the flexible printed circuit board has a weight lighter than the weight of the rigid printed circuit board, the flexible printed circuit board tends to be bent or warped. Therefore, in a component mounting process, mount position accuracy tends to be degraded more than in a general surface mount device (SMD). Moreover, in a solder reflow process, the flexible printed circuit board may be thermally warped due to heating by reflow, and it is also concerned that a positional shift may occur due to the influence of warm air supplied from a reflow device.

As a result, solder reach failure may be invited and, in fact, it is difficult to put surface mount technology (SMT) for flexible printed circuit boards by soldering into practical use. Still further, these problems in solder joints are not limited to the flexible printed circuit board, but may arise when a light-weight rigid printed circuit board is subjected to solder mounting. Therefore, these problems also apply to printed circuit board solder mounting in general.

### SUMMARY

According to an aspect of the invention, a printed circuit board solder mounting method of solder-jointing a first-land formed on a first-printed-circuit-board and a second-land formed on a second-printed-circuit-board together, includes: filling a solder-filling-hole with cream solder, the solder-filling-hole provided so as to be open in a planar region of the first-land; arranging a solder-drawing-hole so that the solder-drawing-hole and the solder-filling-hole face each other, the solder-drawing-hole being formed so as to be open in a planar region of the second region, having a center position to be superposed on a center position of the solder-filling-hole, and having a solder wettability higher than a solder wettability of the solder-filling-hole; melting the cream solder in the solder-filling-hole by reflow heating and causing at least part of the cream solder to ascend to the solder-drawing-hole facing the solder-filling-hole; and jointing the first-land and the second-land together by solidifying the cream solder interposed between the first-land and the second-land.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram of a printed circuit board unit according to an embodiment;

FIG. 2 is a diagram of a solder mount structure of a relay FPC according to the embodiment;

FIG. 3 is a diagram of a solder mount structure of a relay FPC according to the embodiment;

FIG. 4 is a diagram of a detailed structure of RPC joint parts and FPC joint parts according to the embodiment;

FIG. 5 is a diagram of a sectional structure of each RPC joint part according to the embodiment;

FIG. 6 is a diagram of a sectional structure of the FPC joint part according to the embodiment;

FIG. 7 is diagram (1) of a solder filling process according to the embodiment;

FIG. 8 is diagram (2) of a solder filling process according to the embodiment;

FIG. 9 is diagram (3) of a solder filling process according to the embodiment;

FIG. 10 is a diagram of a mounting process according to the embodiment;

FIG. 11 is a diagram of the state where the mounting process according to the embodiment has been completed;

FIG. 12 is diagram (1) of a reflow heating process according to the embodiment;

FIG. 13 is diagram (2) of a reflow heating process according to the embodiment;

FIG. 14 is diagram (3) of a reflow heating process according to the embodiment;

FIG. 15 is diagram (4) of a reflow heating process according to the embodiment;

FIG. 16A is diagram (1) for describing correction of a mount error due to reflow heating according to the embodiment;

FIG. 16B is diagram (2) for describing correction of a mount error due to reflow heating according to the embodiment;

FIG. 17 is a diagram of a printed circuit board unit of related art;

FIG. 18 is a diagram for describing a detailed structure of RPC joint parts and FPC joint parts according to a first modification example;

FIG. 19A is diagram (1) for describing correction of a mount error due to reflow heating according to the embodiment;

FIG. 19B is diagram (2) for describing correction of a mount error due to reflow heating according to the embodiment;

FIG. 20 is a diagram for describing a detailed structure of RPC joint parts and FPC joint parts according to a second modification example;

FIG. 21 is a diagram schematically depicting the state of heat warping occurring to the relay FPC at the time of reflow heating;

FIG. 22A is diagram (1) for describing correction of a mount error due to reflow heating according to the embodiment;

FIG. 22B is diagram (2) for describing correction of a mount error due to reflow heating according to the embodiment;

FIG. 23 is a diagram for describing a detailed structure of RPC joint parts and FPC joint parts according to a third modification example;

FIG. 24 is a diagram of a first variation of a printed circuit board unit to which the printed circuit board solder mounting method and solder mount structure according to the embodiment is applied;

FIG. 25 is a diagram of a second variation of a printed circuit board unit to which the printed circuit board solder mounting method and solder mount structure according to the embodiment is applied; and

FIG. 26 is a diagram of a third variation of a printed circuit board unit to which the printed circuit board solder mounting method and solder mount structure according to the embodiment is applied.

### DESCRIPTION OF EMBODIMENTS

Hereinafter, an embodiment of the printed circuit board solder mounting method and solder mount structure is described with reference to the drawings.

### Embodiment

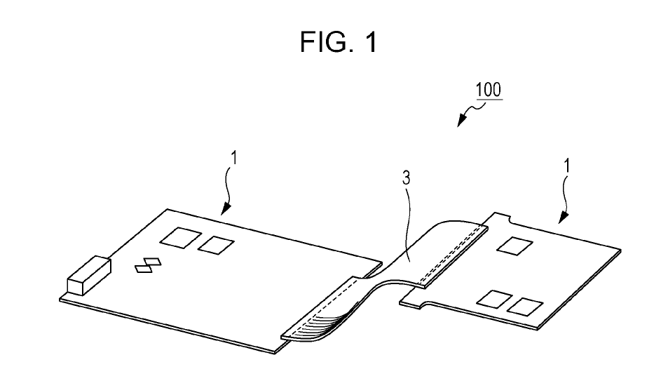

FIG. 1 is a diagram of a printed circuit board unit 100 according to the embodiment. The printed circuit board unit 100 includes paired rigid printed circuit boards 1 and a relay flexible printed circuit board (hereinafter referred to as a relay FPC) 3 which relays the rigid printed circuit boards 1. The paired rigid printed circuit boards 1 are rigid printed wiring boards using a rigid insulating base material. The rigid printed circuit boards 1 are an example of rigid printed circuit boards and, for example, may be glass epoxy printed circuit boards. Also, one of the paired rigid printed circuit boards 1 may be formed as a main board where a CPU and so on are mounted. Furthermore, the other one of the paired rigid printed circuit boards 1 may be formed as a sub-board where an additional RAM and so on are mounted. The relay FPC 3 is a flexible printed wiring board using a thin, flexible material as an insulating base material. As a base material of the relay FPC 3, for example, a polyimide may be used. However, the material for use is not limited to polyimides.

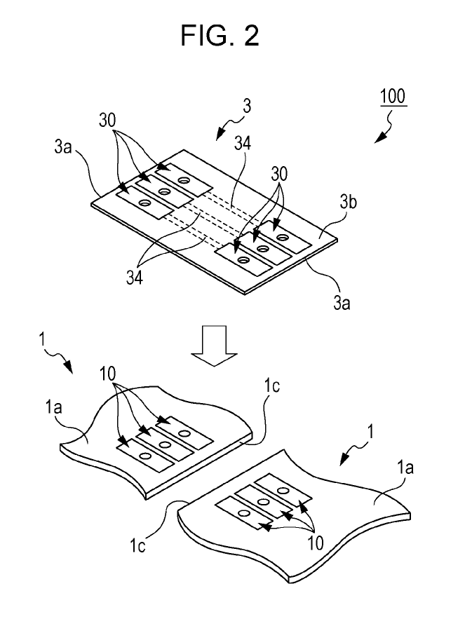

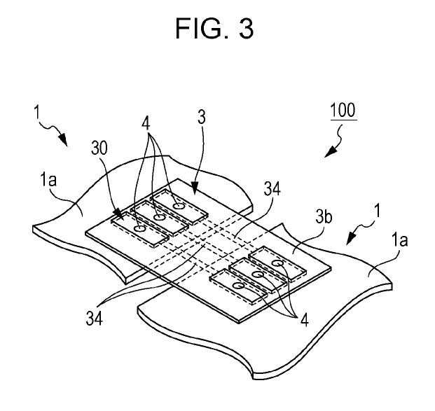

The relay FPC 3 is solder-jointed to both of the rigid printed circuit boards 1 at both ends. Via this relay FPC 3, the paired rigid printed circuit boards 1 are relayed. FIGS. 2 and 3 are diagrams for describing a solder mount structure of the relay FPC 3. FIG. 2 is an exploded view of the state before the relay FPC 3 is mounted on the paired rigid printed circuit boards 1. FIG. 3 depicts the state where mounting of the relay FPC 3 on the paired rigid printed circuit boards 1 has been completed. A reference character is in FIG. 2 denotes an upper surface of each rigid printed circuit board 1.

FPC joint parts 30 are provided at both ends of the relay FPC 3. As depicted in FIGS. 2 and 3, the relay FPC 3 has a rectangular shape. A reference character 3a denotes an end face positioned on each of short sides of the relay FPC 3 in a set. Each of the paired rigid printed circuit boards 1 is provided with RPC joint parts 10. As depicted in FIG. 3, in the present embodiment, the FPC joint parts 30 provided on end face 3 sides of the relay FPC 3 are solder-jointed to the RPC joint parts 10 of each of the rigid printed circuit boards 1. A reference numeral 4 in FIG. 3 denotes a solder jointing material which joints the RPC joint parts 10 and the FPC joint parts 30 together.

The FPC joint parts 30 of the relay FPC 3 are provided as many as the number of RPC joint parts 10 of each rigid printed circuit board 1. In an example depicted in FIGS. 2 and 3, three RPC joint parts 10 are provided to each rigid printed circuit board 1. Therefore, three FPC joint parts 30 are provided to each end face 3a of the relay FPC 3. However, the number of RPC joint parts 10 provided to each rigid printed circuit board 1 is not restricted to a specific number.

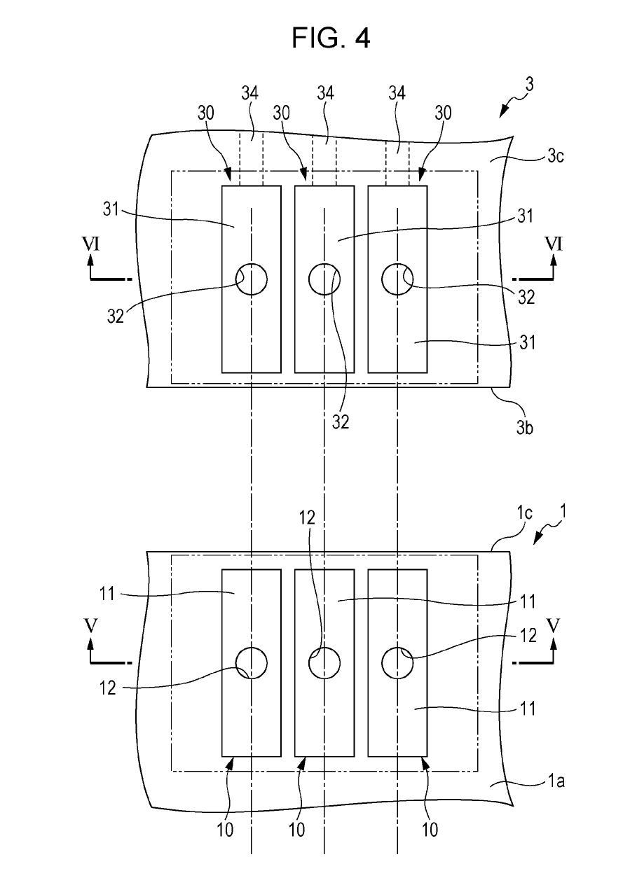

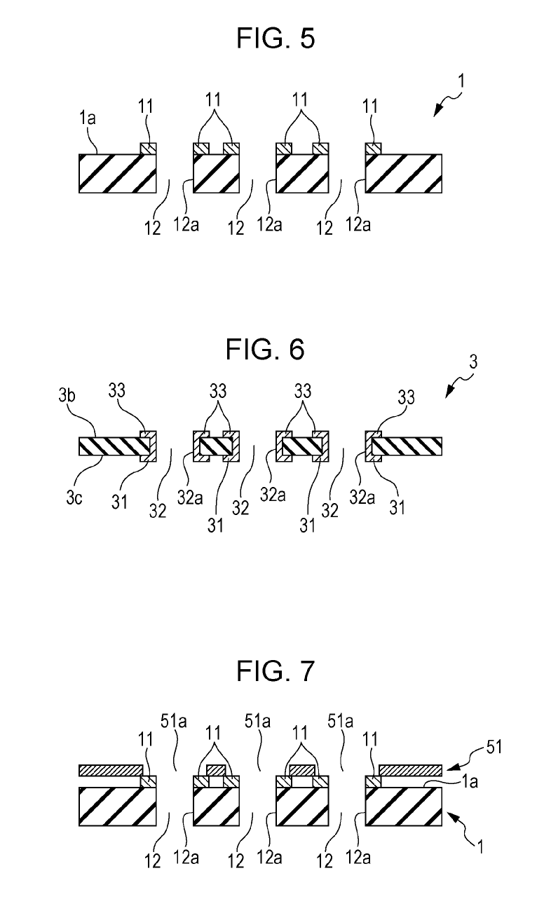

Next, a solder mount structure for solder-jointing the RPC joint parts 10 and the FPC joint parts 30 is described. FIGS. 4 to 6 are diagrams of a detailed structure of the RPC joint parts 10 and the FPC joint parts 30. In an upper part of FIG. 4, a lower surface of the relay FPC 3 is depicted. In a lower part of FIG. 4, an upper surface of the rigid printed circuit board 1 is depicted. FIG. 5 is a diagram of a sectional structure of each RPC joint part 10. FIG. 6 is a diagram of a sectional structure of each FPC joint part 30. FIGS. 4 to 6 each depict the state before the RPC joint parts 10 and the FPC joint parts 30 are solder-jointed together.

A reference character 3b in FIG. 4 denotes an upper surface of the relay FPC 3. A reference character 3c denotes a lower surface of the relay FPC 3. The relay FPC 3 is mounted on the rigid printed circuit board 1 so that the lower surface 3c of the relay FPC 3 faces the upper surface is of each rigid printed circuit board 1.

As depicted in the lower part of FIG. 4, the RPC joint parts 10 each have an RPC land 11 formed on the upper surface is of the rigid printed circuit board 1 and a solder filling hole 12 penetrating through the rigid printed circuit board 1 in a thickness direction. The RPC land 11 is formed so as to be exposed to the upper surface is of the rigid printed circuit board 1, and has a strip shape (a rectangular shape). Each RPC land 11 is formed near an end face is of the rigid printed circuit board 1. A longitudinal direction (a long-side direction) of each RPC land 11 is orthogonal to the end face is of the rigid printed circuit board 1, and the RPC lands 11 are arranged in parallel with each other.

The sectional structure of the RPC joint parts 10 depicted in FIG. 5 illustrates a section along a V-V arrow depicted in FIG. 4. In the present embodiment, the solder filling holes 12 are formed so as to be open in a planar region of each RPC land 11. While one solder filling hole 12 is provided so as to be open in the planar region of each RPC land 11 in the present embodiment, the number of solder filling holes 12 may be changed as appropriate. The solder filling hole 12 is bored so as to penetrate through the rigid printed circuit board 1 in the thickness direction, as depicted in FIG. 5. The solder filling hole 12 has an inner surface 12a where the insulating base material of the rigid printed circuit board 1 is exposed without being processed, that is, naked. That is, the solder filling hole 12 is formed as a so-called non-through hole. This solder filling hole 12 is used to fill cream solder (solder paste) forming the solder jointing material 4 for solder-jointing the RPC joint part 10 and the FPC joint part 30 together. The RPC land 11 is formed of, for example, a conductor such as a copper foil. In the present embodiment, the solder filling holes 12 in the respective RPC joint parts 10 have the same diameter.

As depicted in the upper part of FIG. 4, the FPC joint parts 30 each have an FPC land 31 formed on the lower surface 3c of the relay FPC 3, a solder drawing hole 32 penetrating through the relay FPC 3 in the thickness direction, and a second FPC land 33 formed on the upper surface 3b. The FPC land 31 is formed so as to be exposed to the lower surface 3c of the relay FPC 3, and has a strip shape (a rectangular shape). In the present embodiment, the FPC land 31 has the same shape and size as the RPC land 11 provided on the rigid printed circuit board 1. Also as depicted in FIG. 4, three FPC lands 31 are formed near the end face 3a of the relay FPC 3. A longitudinal direction (a long-side direction) of each FPC land 31 is orthogonal to the end face 3a of the relay FPC 3, and the FPC lands 31 are arranged in parallel with each other.

The sectional structure of the FPC joint parts 30 depicted in FIG. 6 illustrates a section along a VI-VI arrow depicted in FIG. 4. As depicted in FIGS. 4 and 6, the second FPC lands 33 having substantially the same shape and size as the FPC lands 31 formed on the lower surface 3c are formed on the upper surface 3b of the relay FPC 3 so as to be exposed therefrom. The FPC lands 31 and the second FPC lands 33 are formed of, for example, a conductor such as a copper foil.

The solder drawing holes 32 penetrate through the relay FPC 3 in the thickness direction, and one solder drawing hole 32 is provided to each FPC land 31 (each FPC joint part 30). In the present embodiment, the solder drawing holes 32 that are open to the respective FPC lands 31 have the same diameter, which is also the same as the diameter of each solder filling hole 12 on the rigid printed circuit board 1. Also, each solder drawing hole 32 has one end open in a planar region of the FPC land 31 and another end open in a planar region of the second FPC land 33. That is, the solder drawing hole 32 has an edge surrounded by the FPC land 31 and the second FPC land 33. Furthermore, the solder drawing hole 32 has an inner surface 32a coated with metal plating (a metal film) such as copper plating or gold plating. That is, the solder drawing hole 32 is formed by coating the inner surface of the hole penetrating through the relay FPC 3 in the thickness direction with the metal film.

Here, while the solder drawing hole 32 of the relay FPC 3 is a through hole with the inner surface 32a coated with the metal film, the solder filling hole 12 of the rigid printed circuit board 1 is a non-through hole with the insulating base material exposed to the inner surface 12a. As a result, the inner surface 32a of the solder drawing hole 32 in the relay FPC 3 has a solder wettability relatively higher than the solder wettability of the inner surface 12a of the solder filling hole 12 in the rigid printed circuit board 1. That is, the inner surface 32a of the solder drawing hole 32 has a solder wetting compatibility higher than the solder wetting compatibility of the inner surface 12a of the solder filling hole 12.

A reference numeral 34 depicted in FIG. 4 denotes a signal path of the relay FPC 3. The signal path 34 is formed of a conductor such as a copper foil, and is connected to each of the FPC lands 31 arranged at both ends of the relay FPC 3. That is, the FPC lands 31 formed at both ends of the relay FPC 3 are connected via the signal path 34. The signal path 34 is coated with a protective film.

Next, a correspondence between the solder filling hole 12 in the rigid printed circuit board 1 and the solder drawing hole 32 in the relay FPC 3 is described. In the present embodiment, a relative positional relation between the solder drawing hole 32 and the solder filling hole 12 is determined so that when the relay FPC 3 and the rigid printed circuit board 1 are aligned as specified, centers of the solder drawing hole 32 and the solder filling hole 12 that correspond to each other are superposed each other.

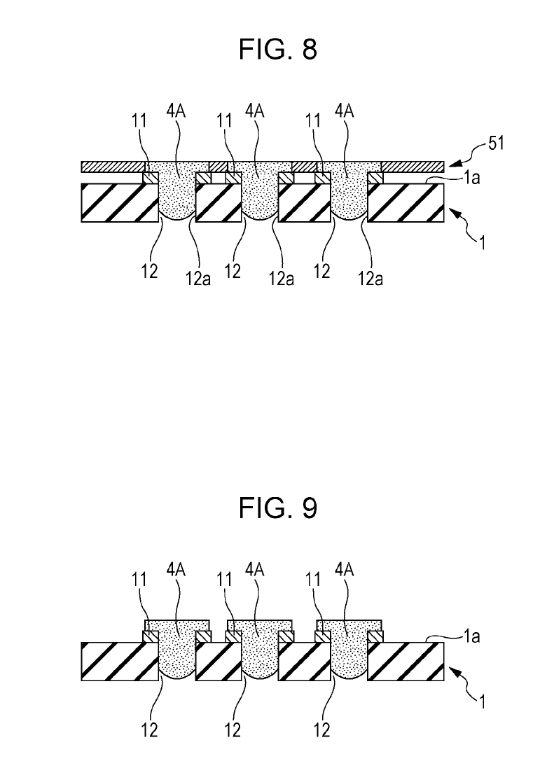

Next, a method of mounting the relay FPC 3 is described. First, the relay FPC 3 including the FPC joint parts 30 described above and the paired rigid printed circuit boards 1 including the RPC joint parts 10 are prepared. Then, first, as depicted in FIG. 3, the paired rigid printed circuit boards 1 are arranged with the upper surface is facing upward. Then, a cream solder printing machine (not depicted) is used to fill each solder filling hole 12 in the rigid printed circuit boards 1 with cream solder (a solder filling process). Specifically, as depicted in FIG. 7, a metal mask 51 is set on the upper surface is of the rigid printed circuit board 1. This metal mask 51 is provided with openings 51a. Then, cream solder (solder paste) 4A is supplied from the cream solder printing machine onto the metal mask 51, and the openings 51a are filled with the cream solder 4A by using a squeegee (not depicted). The openings 51a of the metal mask 51 are formed so as to correspond to the arrangement pattern of the solder filling holes 12 in the rigid printed circuit board 1, and each have an opening area slightly larger than the solder filling hole 12. As a result, as depicted in FIG. 8, the solder filling holes 12 are filled with the cream solder 4A though the openings 51a of the metal mask 51. Also, the cream solder 4A is transferred on to the RPC lands 11 each surrounding the solder filling hole 12. FIG. 9 depicts the state where the metal mask 51 is withdrawn after the solder filling holes 12 of the rigid printed circuit board 1 is filled with cream solder 4A.

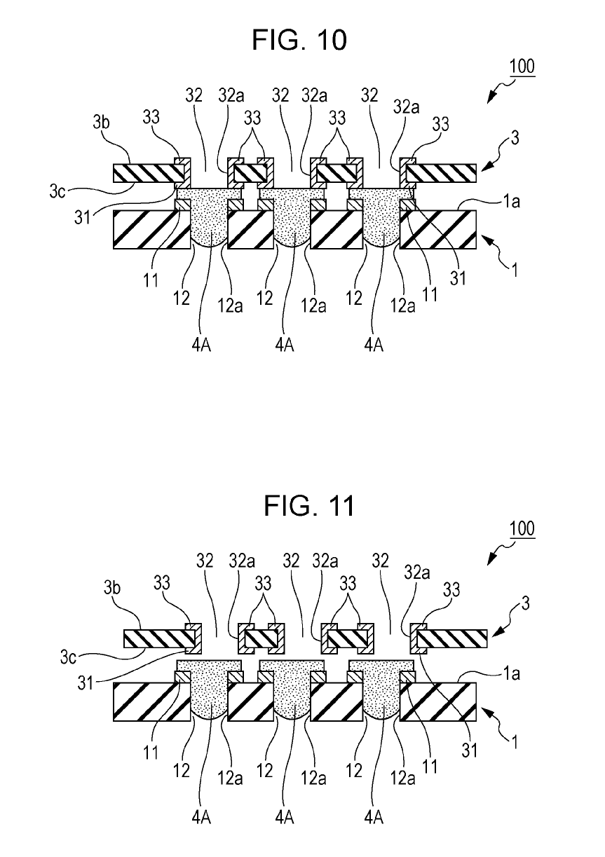

Next, as depicted in FIG. 10, the relay FPC 3 is mounted (placed) on the rigid printed circuit boards 1 so that the center position of each solder drawing hole 32 in the relay FPC 3 coincides with the center position of each corresponding solder filling hole 12 in the rigid printed circuit board 1 (a mounting process). Here, the relay FPC 3 is arranged so as to face the rigid printed circuit boards 1 so that the lower surface 3c of the relay FPC 3 faces the upper surface is of each rigid printed circuit board 1. Specifically, while the relay FPC 3 is aligned with respect to the rigid printed circuit boards 1, the FPC lands 31 of the relay FPC 3 are mounted (installed) on the RPC lands 11 of the rigid printed circuit boards 1. With this, the solder drawing holes 32 of the relay FPC 3 and the solder filling holes 12 of the rigid printed circuit boards 1 are arranged so as to face each other. In this state, as depicted in FIG. 10, the FPC lands 31 of the relay FPC 3 are mounted on the RPC lands 11 across the cream solder 4A on the RPC lands 11. Therefore, in this state, the FPC lands 31 are in contact with the cream solder 4A.

Meanwhile, the relay FPC 3 has a weight lighter than each rigid printed circuit board 1, and tends to be bent or warped. Therefore, in the process of mounting the relay FPC 3 on the rigid printed circuit boards 1, it is not easy to mount the relay FPC 3 at a normal position, and an error may occur at the mount position of the relay FPC 3. Moreover, if the relay FPC 3 is bent or warped, partial “floating” may occur to the relay FPC 3, and the FPC lands 31 may be separated from the RPC lands 11. FIG. 11 depicts the situation where a positional shift occurs to the relay FPC 3 when the relay FPC 3 is mounted (installed) on the rigid printed circuit boards 1 and a gap occurs between the FPC lands 31 and the cream solder 4A. In the mount structure of related art, when reflow heating is performed with this positional shift or gap occurring, the gap is further increased due to heat warping of the flexible printed circuit board, and therefore solder reach failure disadvantageously tends to occur. For this reason, in related art, it is in fact difficult to solder-mount the flexible printed circuit board and another surface mount device (SMDs) collectively on the rigid printed circuit board.

For example, when the relay FPC 3 is mounted, as depicted in FIG. 11, a positional shift may occur to the relay FPC 3, and a gap may occur between the FPC lands 31 and the cream solder 4A. In the present embodiment, as depicted in FIG. 11, when the relay FPC 3 is mounted on the rigid printed circuit board 1, even if a positional shift or gap occurs, the positional shift or gap is solved by a self alignment action (effect) of the solder at the time of reflow heating. Reflow heating and the self alignment action exerted at the time of reflow heating are described in detail below.

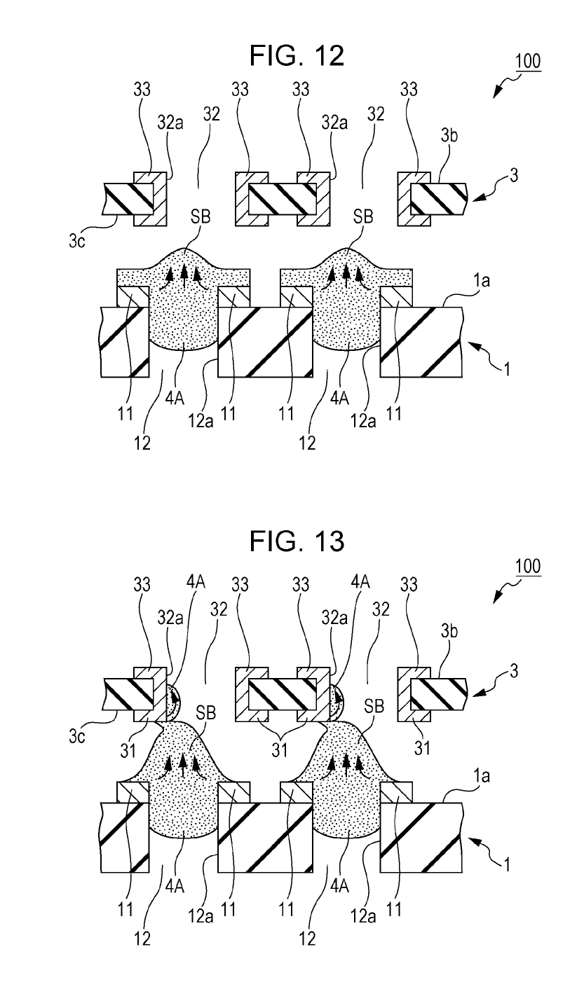

After the relay FPC 3 is mounted on the rigid printed circuit board 1, reflow heating is performed by a reflow furnace (not depicted) (a reflow heating process). It is assumed herein that, as in the state depicted in FIG. 11, an error occurs to the relay FPC 3 and the relay FPC 3 is shifted from the normal mount position at the start of reflow heating. When the cream solder 4A filled in the solder filling holes 12 of the rigid printed circuit board 1 is heated by reflow heating, the cream solder 4A is melted to thermally expand in the solder filling holes 12. The RPC lands 11 are each formed of a conductor such as a copper foil, and has a solder wettability higher than the solder wettability of the inner surface 12a where the insulating resin is exposed. When reflow heating is performed under this condition, the thermal expansion pressure of the cream solder 4A and the difference in solder wettability between the RPC lands 11 and the inner surface 12a of each solder filling hole 12 cause the cream solder 4A to ascend to the RPC lands 11 and be pushed upward and outward from the solder filling holes 12. As a result, as depicted in FIG. 12, the cream solder 4A pushed upward and outward from each solder filling hole 12 becomes humped higher than the surfaces of the RPC lands 11, thereby forming a projecting shape (hereinafter referred to as a solder bump) SB. FIG. 12 depicts the state of an initial stage of the reflow heating process, where the melted cream solder 4A ascends to the RPC lands 11 and crawls out from each solder filling hole 12, thereby forming the solder bump SB. The RPC lands 11 are each formed of a conductor such as a copper foil, and has a solder wettability higher than the solder wettability of the inner surface 12a where the insulating resin is exposed.

Here, as the phenomenon of pushing the cream solder 4A from each solder filling hole 12 advances, the height of the solder bump SB increases. As a result, as depicted in FIG. 13, the solder bumps SB make contact with the surface of each FPC land 31. When the relay FPC 3 is heated by reflow heating, the relay FPC 3 may be thermally warped. Even in this case, for example, in consideration of heat warping of the relay FPC 3, the solder filling holes 12 are filled with a sufficient amount of the cream solder 4A. With this, the gap between the FPC lands 31 and the cream solder 4A may be absorbed by the solder bump SB.

As described above, as with the RPC lands 11, the FPC lands 31 have a solder wettability higher than the solder wettability of the solder filling holes 12. Also, the inner surface 32a of each solder drawing hole 32 coated with metal plating has a solder wettability height than the solder wettability of the solder filling holes 12. Therefore, when the solder bump SB (the cream solder 4A) makes contact with the FPC lands 31, the cream solder 4A ascends to the FPC lands 31 with high solder wettability and the metal-plated inner surface 32a of each solder drawing hole 32, and thereby being drawn into each solder drawing hole 32. That is, in the reflow heating process, the cream solder 4A filled in the solder filling holes 12 in the solder filling process may be moved by ascending from the solder filling holes 12 into the solder drawing holes 32 with higher solder wettability.

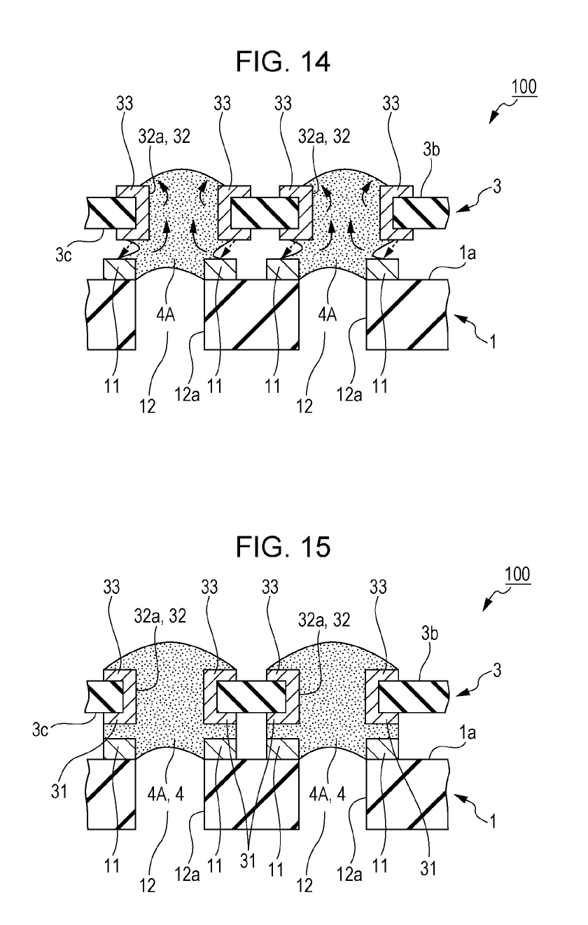

FIG. 14 is a diagram of the state of an intermediate stage of the reflow heating process. In the intermediate stage of the reflow heating process, the movement of the cream solder 4A from the solder filling holes 12 with low solder wettability to the solder drawing holes 32 with high solder wettability has further advanced. As depicted in FIG. 14, when the cream solder 4A ascends to the solder drawing holes 32, the RPC lands 11 and the FPC lands 31 become connected as one via the cream solder 4A. As a result, surface tension of the ascending cream solder 4A acts between the FPC lands 31 of the relay FPC 3 and the RPC lands 11 of the rigid printed circuit boards 1, thereby causing the FPC lands 31 and the RPC lands 11 to be attracted to each other.

Then, as the center of each solder drawing hole 32 is guided in a direction of matching the center of each solder filling hole 12, the FPC lands 31 and the RPC lands 11 are attracted in a direction of approaching each other. Also, when the rigid printed circuit board 1 is taken as a reference, the FPC lands 31 of the relay FPC 3 are attracted to the RPC lands 11 of the rigid printed circuit board 1 so as to resolve a mount error (a positional shift or gap) of the relay FPC 3 mounted (installed) on the rigid printed circuit board 1. Here, broken arrows depicted in FIG. 14 each exemplarily illustrate a direction in which the FPC lands 31 of the relay FPC 3 are attracted to the facing RPC lands 11 at the time of reflow heating. With this self alignment (mount error correction) action, the mount error of the relay FPC 3 occurring in the mounting process may be resolved. Also, since the FPC lands 31 of the relay FPC 3 are attracted in the direction of approaching the facing RPC lands 11, bending or warping of the relay FPC 3 that has already occurred before reflow heating, heat warping occurring due to reflow heating, and so on are resolved. As a result, as depicted in FIG. 15, with the center of each solder drawing hole 32 in the relay FPC 3 and the center of each solder filling hole 12 in the rigid printed circuit board 1 matched on a plane, the gap in a height direction between the FPC lands 31 and the RPC lands 11 may be appropriately corrected. FIG. 15 is a diagram of the state of a final stage of the reflow heating process.

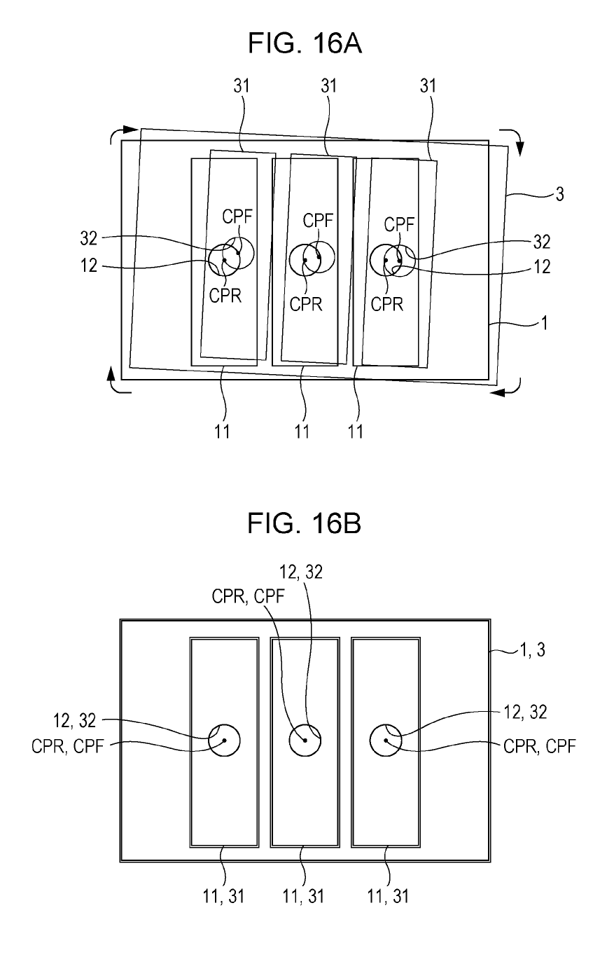

FIGS. 16A and 16B depict the states before and after correction of a mount error due to reflow heating. FIG. 16A conceptually depicts a relative planar positional relation between the relay FPC 3 and the rigid printed circuit board 1 before correction of a mount error due to reflow heating. By contrast, FIG. 16B conceptually depicts a relative planar positional relation between the relay FPC 3 and the rigid printed circuit board 1 after correction of a mount error due to reflow heating. In FIGS. 16A and 16B, the rigid printed circuit board 1 is depicted by a bold line, and the relay FPC 3 is depicted by a fine line. Also, the rigid printed circuit board 1 and the relay FPC 3 depicted in FIGS. 16A and 16B each represent a virtual area surrounded by a two-dot chain line depicted in FIG. 4.

The state depicted in FIG. 16A corresponds to the state depicted in FIG. 11, where a mount error, specifically, a rotation shift, occurs to the relay FPC 3 mounted (installed) on the rigid printed circuit board 1, where the relay FPC 3 is relatively rotated with respect to the rigid printed circuit board 1. Then, as depicted in FIG. 16A, due to the rotation shift of the relay FPC 3, the center positions (CPF in FIG. 16A) of the solder drawing holes 32 and the center positions (CPR in FIG. 16A) of the solder filling holes 12 of the rigid printed circuit board 1 are shifted from each other in a planar sense.

By contrast, when reflow heating starts as described above, at least part of the cream solder 4A filled in the solder filling hole 12 is melted at the time of reflow heating to ascend to the inside of each solder drawing hole 32. As such, with surface tension of the cream solder 4A when ascending from the solder filling holes 12 to the solder drawing holes 32, the self alignment (mount error correction) action described above is exerted. As a result, as depicted in FIG. 16B, the center position (CPF) of each solder drawing hole 32 matches the center position (CPR) of each solder filling hole 12. With this, the error of a mount position occurring when the relay FPC 3 is mounted on the rigid printed circuit board 1 may be resolved.

Meanwhile, in the relay FPC 3 according to the present embodiment, the solder drawing holes 32 are formed as through holes, and the second FPC lands 33 are provided to the edge of the solder drawing holes 32 on the upper surface 3b. Accordingly, as depicted in FIGS. 14 and 15, while correction of a mount error of the relay FPC 3 at the time of reflow heating is performed, the cream solder 4A moved from the solder filling holes 12 to the solder drawing holes 32 is caused to ascend from the solder drawing holes 32 to the second FPC lands 33. That is, at the time of reflow heating, while the amount of the cream solder 4A for solder-jointing the RPC joint parts 10 and the FPC joint parts 30 together is ensured, a superfluous amount of the cream solder 4A may be moved from the solder drawing holes 32 onto the second FPC lands 33. As a result, a short circuit between adjacent FPC lands 31 or between adjacent RPC lands 11 may be suppressed. Here, the solder drawing holes 32 may be each formed as a non-through hole that is open in the planar region of the FPC land 31 and does not penetrate through the relay FPC 3. This is because, by moving the cream solder 4A in the solder filling holes 12 to the solder drawing holes 32 with a solder wettability relatively higher than the solder wettability of the solder filling holes 12 at the time of reflow heating, a mount error of the relay FPC 3 and heat warping occurring at the time of reflow heating are resolved. The second FPC lands 33 are an example of a third land.

As depicted in FIG. 15, in the present embodiment, upon completion of correction of the mount error of the relay FPC 3, a solder joint part between the relay FPC 3 and the rigid printed circuit board 1 is cooled. As a result, as depicted in FIG. 15, the cream solder 4A interposed between the FPC lands 31 of the relay FPC 3 arranged to face each other and the RPC lands 11 of the rigid printed circuit board 1 is solidified (hardened). As such, the FPC lands 31 of the relay FPC 3 and the RPC lands 11 of the rigid printed circuit board 1 are solder-jointed via the solder jointing material 4 formed by the solidified cream solder 4A, thereby completing mounting of the relay FPC 3 on the rigid printed circuit board 1.

As described above, according to the solder mount structure (mounting method) of the relay FPC 3 according to the present embodiment, at least part of the cream solder 4A filled in the solder filling holes 12 is melted at the time of reflow heating and ascends into the solder drawing holes 32. Then, with the cream solder 4A pushed from the solder drawing holes 32 being interposed between the RPC lands 11 and the FPC lands 31, the cream solder 4A is solidified to form the solder jointing material 4, thereby jointing the FPC lands 31 and the RPC lands 11. Here, since the self alignment effect is exerted by surface tension of the cream solder 4A ascending from the solder filling holes 12 to the solder drawing holes 32, solder reach failure may be suppressed while a positional shift, heat warping, and so on of the relay FPC 3 may be resolved.

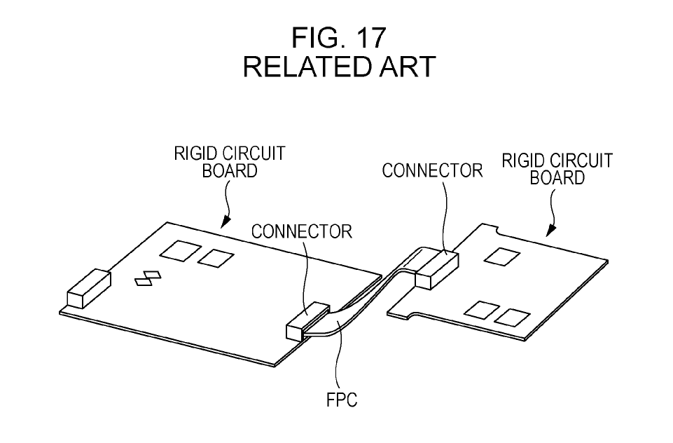

Also, according to the solder mount structure (mounting method) of the relay FPC 3 according to the present embodiment, a light-weight and flexible printed circuit board such as an FPC and another surface mount device (SMD) are allowed to be collectively solder-mounted. As a result, the number of processes at the time of manufacturing the printed circuit board unit 100 is decreased, and manufacturing efficiency may be improved. Also, unlike the connecting scheme using a connector in related art as depicted in FIG. 17, an FPC is allowed to be jointed to the rigid printed circuit board without using a connector (in a connectorless manner) in the present embodiment. With this, high-density mounting of the printed circuit board unit is performed, and electronic devices may be easily made thinner. Furthermore, since the FPC is allowed to be jointed in a connectorless manner, it is possible to suitably suppress secondary trouble as in the past, such as degradation of operability at the time of circuit board assembling and damage to the connector body or a peripheral component at the time of connector coupling.

Furthermore, the relay FPC 3 and another surface mount device (SMD) are allowed to be collectively solder-mounted without a special thermocompression process or dedicated device as in a jointing scheme with the anisotropic conductive film (ACF) or the anisotropic conductive paste (ACP). With this, the number of processes at the time of printed board assembling is decreased, and electronic device manufacturing efficiency is improved. In the present embodiment, an example is described in which the rigid printed circuit board 1 and the relay FPC 3 are a first printed circuit board and a second printed circuit board, respectively. Still further, in this example, the RPC lands 11 of the rigid printed circuit board 1 and the FPC lands 31 of the relay FPC 3 are a first land and a second land, respectively.

While the solder filling holes 12 are formed as through holes penetrating the rigid printed circuit board 1 in the thickness direction in the present embodiment, the solder filling holes 12 may be formed as non-through holes. The solder filling holes 12 may be formed as closed-end holes as long as it is possible to fill a sufficient amount of the cream solder 4A for bringing the solder bump formed at the time of reflow heating into contact with FPC lands 31. That is, the solder filling holes 12 may be formed as closed-end holes as long as the height of the solder bump SB formed by the melted cream solder 4A (hereinafter referred to as a solder bump height) is appropriately ensured. Even with these closed-end holes (non-through holes), the self alignment effect described above at the time of reflow heating is suitably exerted.

Also, in the present embodiment, for solder-mounting of the relay FPC 3, each solder filling hole 12 and each solder drawing hole 32 arranged to face each other are set to have the same diameter. As such, by setting the same hole diameter for the solder filling hole 12 and the solder drawing hole 32 corresponding to each other, the height of the solder bump SB at the time of reflow heating and the capacity for retreating superfluous solder to the upper surface 3b of the relay FPC 3 are favorably balanced. For example, as the diameter of the solder filling hole 12 increases, the amount of the cream solder 4A filled in the solder filling hole 12 in the solder filling process increases. For this reason, the height of the solder bump formed of the melted cream solder 4A increases, and the superfluous amount of the cream solder 4A tends to increase. Thus, by associating the hole diameter of the solder filling hole 12 and the hole diameter of the solder drawing hole 32 with each other, as the filling amount of the cream solder 4A to the solder filling hole 12 increases, the capacity of the solder drawing hole 32 for drawing (retreating) superfluous cream solder 4A increases. As a result, even when the filling amount of the cream solder 4A filled in the solder filling holes 12 is large, the capacity of the solder drawing hole 32 for receiving (retreating) the cream solder 4A increases in accordance with the filling amount. Therefore, a short circuit between adjacent FPC lands 31 or between adjacent RPC lands 11 may be suppressed.

Furthermore, in the present embodiment, the plurality of corresponding RPC lands 11 and FPC lands 31 are formed on the rigid printed circuit board 1 and the relay FPC 3. Furthermore, at least one or more solder filling holes 12 are arranged in the planar region of each RPC land 11, and at least one or more solder drawing holes 32 are arranged in the planer region of each FPC land 31. According to this, the self alignment action described above is exerted for each combination of the RPC land 11 and the FPC land 31 arranged to face each other at the time of reflow heating, thereby more favorably increasing mount accuracy of the relay FPC 3.

The solder mounting method and solder mount structure according to the present embodiment may be variously modified. Various modification examples according to the present embodiment are described below.

### First Modification Example

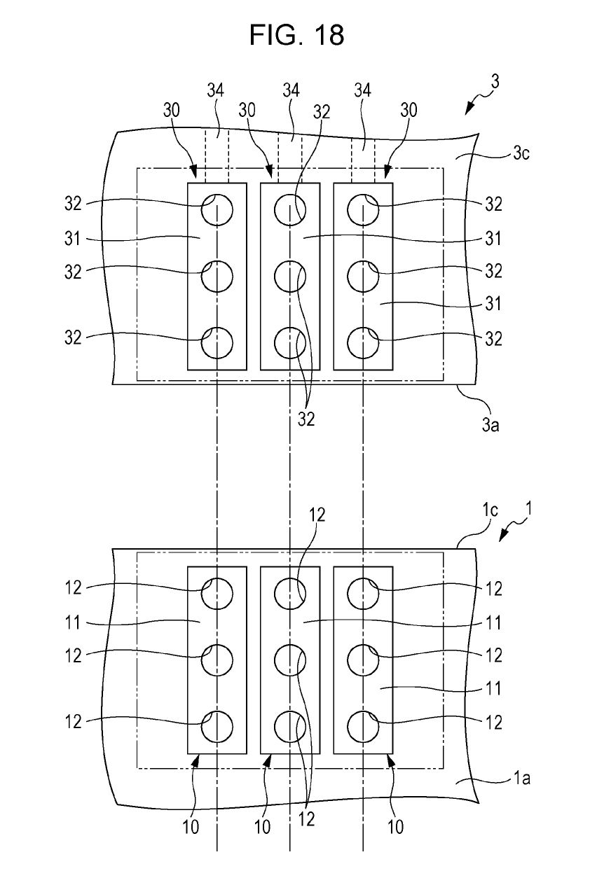

FIG. 18 is a diagram for describing a detailed structure of the RPC joint parts 10 and the FPC joint parts 30 according to a first modification example, and corresponds to FIG. 4 in the above-described embodiment. In an upper part of FIG. 18, the lower surface of the relay FPC 3 is depicted. In a lower part of FIG. 18, the upper surface of the rigid printed circuit board 1 is depicted. The sectional structures of the RPC joint parts 10 and the FPC joint parts 30 are similar to the sectional structures in the above-described embodiment, and FIG. 5 and FIG. 6 are applicable. To mount the relay FPC 3 on the rigid printed circuit board 1, the relay FPC 3 is mounted on the rigid printed circuit board 1 so that the upper surface is of the rigid printed circuit board 1 depicted in the lower part of FIG. 18 and the lower surface 3c of the relay FPC 3 depicted in the upper part of FIG. 18 face each other.

In the present modification example, a plurality of solder filling holes 12 are arranged in a planar region of each RPC land 11 formed on the upper surface is of the rigid printed circuit board 1. Also, a plurality of solder drawing holes 32 are arranged in a planar region of each FPC land 31 formed on the lower surface 3c of the relay FPC 3. In an example depicted in FIG. 18, three solder filling holes 12 are arranged on each RPC land 11, and three solder filling holes 12 are arranged on each FPC land 31. Also, the solder filling hole 12 and the solder drawing hole 32 facing each other are determined to have the same diameter when the rigid printed circuit board 1 is mounted on the relay FPC 3.

As in the present modification example, by arranging the plurality of solder filling holes 12 (solder drawing holes 32) on each RPC land 11 (each FPC land 31), a positional shift of the relay FPC 3 is corrected at the plurality of points per RPC land 11 (FPC land 31). As a result, the accuracy of the mount position of the relay FPC 3 is further increased, and solder reach failure may be reliably suppressed.

Also, as depicted in FIG. 18, the plurality of solder drawing holes 32 are arranged so as to be aligned along a direction orthogonal to the end face 3a of the relay FPC 3 in the planar region of each FPC land 31 in the present modification example. That is, in the present modification example, the plurality of solder drawing holes 32 are arranged so as to be aligned along a longitudinal direction of the relay FPC 3 in the planar region of each FPC land 31. In other words, the plurality of solder drawing holes 32 are arranged so as to be aligned along a direction in which the relay FPC 3 approaches and goes away from the rigid printed circuit board 1, in the planar region of each FPC land 31. The direction in which the relay FPC 3 approaches and goes away is regarded as the longitudinal direction of the relay FPC 3 or a direction orthogonal to the end face is of the rigid printed circuit board 1. On the other hand, as for the rigid printed circuit board 1, the plurality of solder filling holes 12 are arranged so as to be aligned along a direction orthogonal to the end face is in the planar region of each RPC land 11. With this, the plurality of solder filling holes 12 are arranged so as to be aligned at positions corresponding to the plurality of solder drawing holes 32 in the relay FPC 3 in the planar region of each RPC land 11.

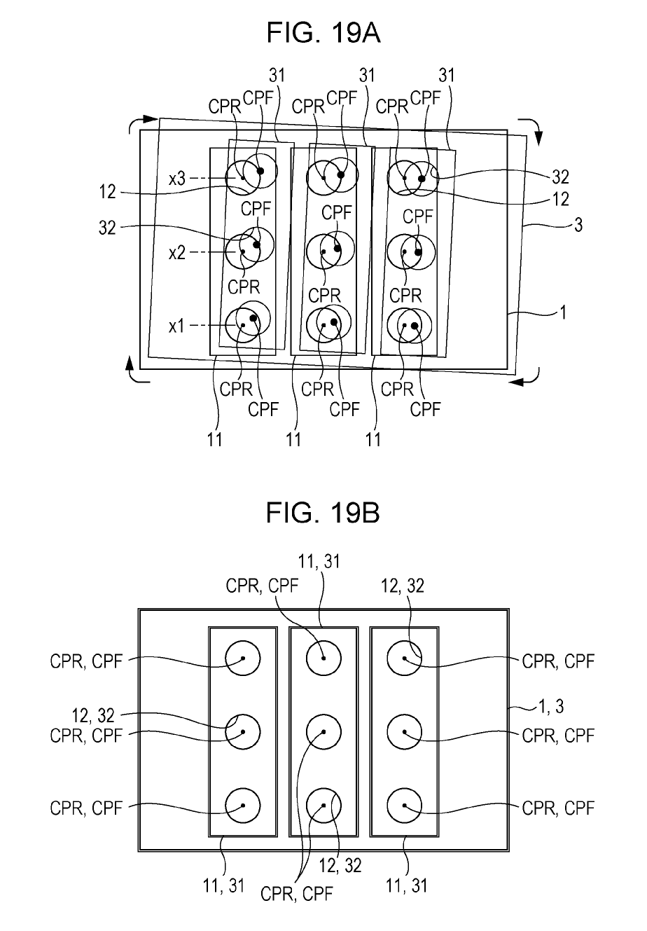

FIGS. 19A and 19B are diagrams of the states before and after correction of a mount error due to reflow heating, and correspond to FIG. 16A and FIG. 16B, respectively. It is assumed that a rotational shift of the relay FPC 3 occurs as depicted in FIG. 19A when the relay FPC 3 is mounted on the rigid printed circuit board 1 in the mounting process. In FIGS. 19A and 19B, the center position of each solder drawing hole 32 and the center position of each solder filling hole 12 are represented by CPF and CPR, respectively. In FIG. 19A, in view of drawing creation, dots representing the center positions CPF of the semiconductor drawing holes 32 are presented larger than dots representing the center positions of the solder filling holes 12.

When a rotational shift occurs to the relay FPC 3, the shift amount between the centers of the solder filling hole 12 and the solder drawing hole 32 (hereinafter referred to as an intercenter shift amount) varies depending on the position (represented by x1, x2, or x3 in FIG. 19A) in the direction in which the relay FPC 3 approaches and goes away. In an example depicted in FIG. 19A, the intercenter shift amount between the solder filling hole 12 and the solder drawing hole 32 corresponding to x1 is minimum, and the intercenter shift amount increases with transition to x2 and then x3. As the intercenter shift amount increases, a superposing area where the solder filling hole 12 and the solder drawing hole 32 overlap each other decreases. When the intercenter shift amount between the solder filling hole 12 and the solder drawing hole 32 in a set is too large (when the superposing area is too small), the self alignment effect at the time of reflow heating may not be sufficiently exerted.

In the present modification example, attention is directed to the fact that when a rotational shift occurs to the relay FPC 3, the intercenter shift amount varies in accordance with the position in the direction in which the relay FPC 3 approaches and goes away, and the solder drawing holes 32 are aligned along the direction in which the relay FPC 3 approaches and goes away. In addition, the solder filling holes 12 are also arranged so as to be aligned in association with the solder drawing holes 32 along the direction in which the relay FPC 3 approaches and goes away. According to this arrangement, even if a pair of the solder filling hole 12 and the solder drawing hole 32 with a too large intercenter shift amount is present in the planar region of a set of the FPC land 31 and the RPC land 11, the positional shift of the relay FPC 3 is correctable sequentially from a pair with a relatively small intercenter shift amount.

For example, it is assumed in the example depicted in FIG. 19A that the positional shift of the relay FPC 3 is corrected only for a set (pair) of the solder drawing hole 32 and the solder filling hole 12 corresponding to x1 with the smallest intercenter shift amount at the time of reflow heating. By correcting the positional shift of the relay FPC 3 from a portion where the intercenter shift amount between the solder drawing hole 32 and the solder filling hole 12 is relatively small, the intercenter shift amounts between the solder drawing hole 32 and the solder filling hole 12 corresponding to other parts (x2 and x3) become smaller than the intercenter shift amounts at the start of reflow. As a result, the positional shift becomes correctable sequentially for x2 and x3 for which the positional shift of the relay FPC 3 is not correctable initially at the start of reflow.

As described above, in the present modification example, the positional shift of the relay FPC 3 becomes correctable sequentially (in a stepwise manner) from a part with a small intercenter shift amount between the solder drawing hole 32 and the solder filling hole 12 in the direction in which the relay FPC 3 approaches and goes away. As a result, the centers are allowed to be matched with accuracy for all combinations of the solder drawing holes 32 and the solder filling holes 12, thereby more suitably increasing mount accuracy of the relay FPC 3.

### Second Modification Example

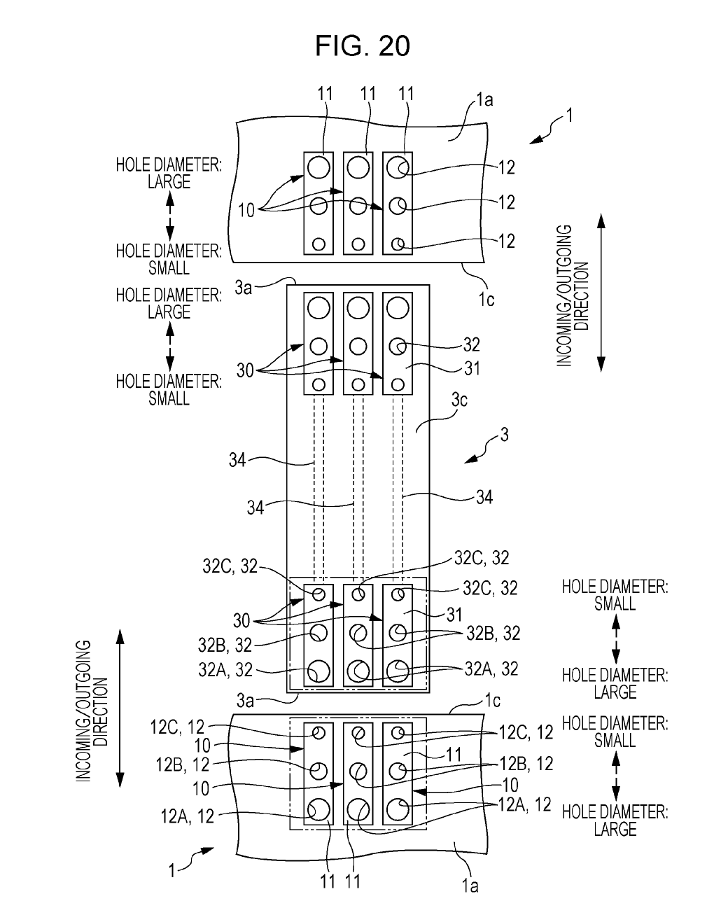

FIG. 20 is a diagram for describing a detailed structure of the RPC joint parts 10 and FPC joint parts 30 according to a second modification example. As with FIGS. 4 and 18, FIG. 20 depicts the state before solder-jointing the RPC joint parts 10 and the FPC joint parts 30. FIG. 20 depicts the lower surface 3c of the relay FPC 3 and the upper surface is of the rigid printed circuit board 1.

A difference between the present modification example and the first modification example is mainly described below. The second modification example is similar to the first modification example in that the plurality of solder drawing holes 32 are arranged so as to be aligned in the planar region of each FPC land 31 along the direction orthogonal to the end face 3a of the relay FPC 3. That is, the plurality of solder drawing holes 32 are arranged so as to be aligned in the planar region of each FPC land 31 along the direction in which the relay FPC 3 approaches and goes away the rigid printed circuit board 1 (along the longitudinal direction of the relay FPC 3). Also in the rigid printed circuit board 1, the plurality of solder filling holes 12 are arranged so as to be aligned in the planar region of each RPC land 11 along the direction orthogonal to the end face is of the rigid printed circuit board 1, which is similar to the first modification example.

In the second modification example, among the solder drawing holes 32 arranged on each FPC land 31 in the relay FPC 3, the solder drawing hole 32 with a smaller separation dimension from the end face 3a is set with a larger hole diameter. In FIG. 20, the solder drawing holes 32 arranged on each FPC land 31 are taken as a first solder drawing hole 32A, a second solder drawing hole 32B, and a third solder drawing hole 32C in increasing order of separation dimension from the end face 3a. In an example depicted in FIG. 20, among the first solder drawing hole 32A to the third solder drawing hole 32C, the first solder drawing hole 32A with the smallest separation dimension from the end face 3a in the relay FPC 3 is formed to have the largest diameter, and the third solder drawing hole 32C with the largest separation dimension from the end face 3a in the relay FPC 3 is formed to have the smallest diameter.

In FIG. 20, the solder filling holes 12 in each RPC land 11 are taken as a first solder filling hole 12A, a second solder filling hole 12B, and a third solder filling hole 12C in decreasing order of separation dimension from the end face 1c. In the present modification example, among the solder filling holes 12 arranged on one RPC land 11 in the rigid printed circuit board 1, the solder filling hole 12 corresponding to the solder drawing hole 32 with a smaller separation dimension from the end face 3a of the relay FPC 3 is formed to have a larger hole diameter. Therefore, in the example depicted in FIG. 20, among the first solder filling hole 12A to the third solder filling hole 12C, the first solder filling hole 12A with the largest separation dimension from the end face is in the rigid printed circuit board 1 is formed to have the largest diameter, and the third solder filling hole 12C with the smallest separation dimension from the end face is in the rigid printed circuit board 1 is formed to have the smallest diameter.

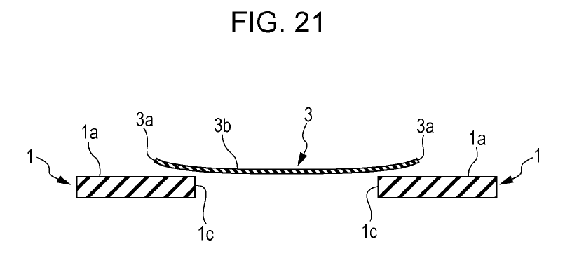

FIG. 21 is a diagram schematically depicting the state of heat warping occurring to the relay FPC 3 at the time of reflow heating. When the relay FPC 3 is thermally warped by reflow heating, the separation dimension from the upper surface is of the rigid printed circuit board 1 increases at a portion closer to the end face 3a. That is, a gap between the FPC lands 31 in height direction increases at a portion closer to the end face 3a in the relay FPC 3. As a result, the solder bump formed of the cream solder 4A at the time of reflow heating has to be mounded to a higher position at a portion closer to the end face 3a. In the present modification example, attention is directed to the fact that as the diameter of the solder filling hole 12 in the rigid printed circuit board 1 is larger, the filling amount of the cream solder 4A filled in the solder filling holes 12 by the printing device is larger, thereby getting a higher solder bump height at the time of reflow heating.

In addition, when the relay FPC 3 is mounted on the rigid printed circuit board 1, the diameter of the solder filling hole 12 (12A) is increased at a portion with a larger gap between the FPC lands 31 in height direction due to heat warping of the relay FPC 3 at the time of reflow heating. With this, a larger capacity of the corresponding solder filling hole 12 is ensured at a portion closer to the end face 3a of the relay FPC 3 where the influence of heat warping is large at the time of reflow heating, thereby filling with the cream solder 4A more in the solder filling process. As a result, the solder bump formed by ascent of the cream solder 4A is mounded higher at a portion closer to the end face 3a of the relay FPC 3 where the influence of heat warping is large at the time of reflow heating. For this reason, even if large warping occurs to the end face 3a of the relay FPC 3 at the time of reflow heating, the solder bump is caused to reliably reach the FPC land 31. With this, the cream solder 4A is allowed to ascend from the solder filling hole 12 to the solder drawing hole 32 even on an end face 3a side of the relay FPC 3 with large heat warping, thereby correcting a mount error of the relay FPC 3 due to surface tension of the cream solder 4A.

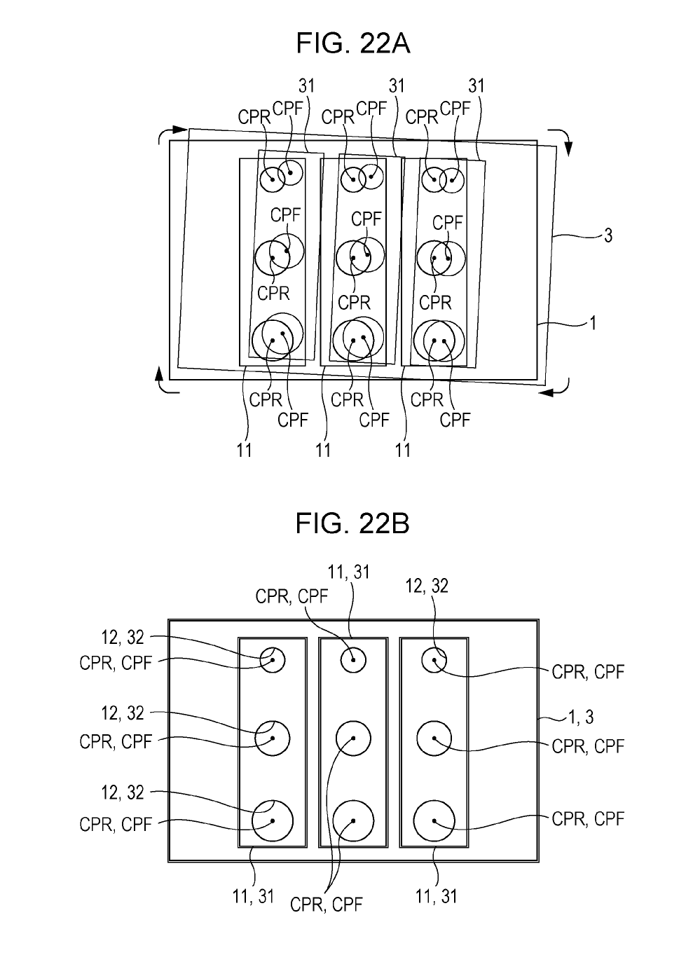

As a result, as depicted in FIG. 22A, when the relay FPC 3 is mounted on the rigid printed circuit board 1, even if a shift in mount position occurs, the mount error correcting effect in the relay FPC 3 is favorably exerted. Thus, as depicted in FIG. 22B, it is possible to match the mount position of the relay FPC 3 with the normal position so that the solder drawing hole 32 and the solder filling hole 12 corresponding to each other match each other. Therefore, the relay FPC 3 is accurately solder-mounted at the normal position while solder reach failure is suppressed. FIGS. 22A and 22B correspond to FIGS. 19A and 19B, respectively, of the first modification example.

Furthermore, in the present modification example, of the solder drawing holes 32 arranged on each FPC land 31 in the relay FPC 3, the solder drawing hole 32 with a smaller separation dimension from the end face 3a has a larger hole diameter. Also when the relay FPC 3 is mounted on the rigid printed circuit board 1, the solder filling hole 12 and the solder drawing hole 32 facing each other are determined to have the same diameter. By adjusting the magnitude of the diameter of each solder drawing hole 32 in accordance with the magnitude of the diameter of each facing solder filling hole 12, the capacity of the facing solder drawing hole 32 is increased in accordance with the capacity of the solder filling hole 12. Here, as the capacity of the solder filling hole 12 is larger, the filling amount of the cream solder 4A filled in the solder filling process increases, and the superfluous amount of the cream solder 4A at the time of reflow heating increases. In the present modification example, the capacity of the solder drawing hole 32 to draw the superfluous cream solder 4A is increased in accordance with the superfluous amount of the cream solder 4A. Therefore, a short circuit between adjacent FPC lands 31 or between adjacent RPC lands 11 may be suppressed.

### Third Modification Example

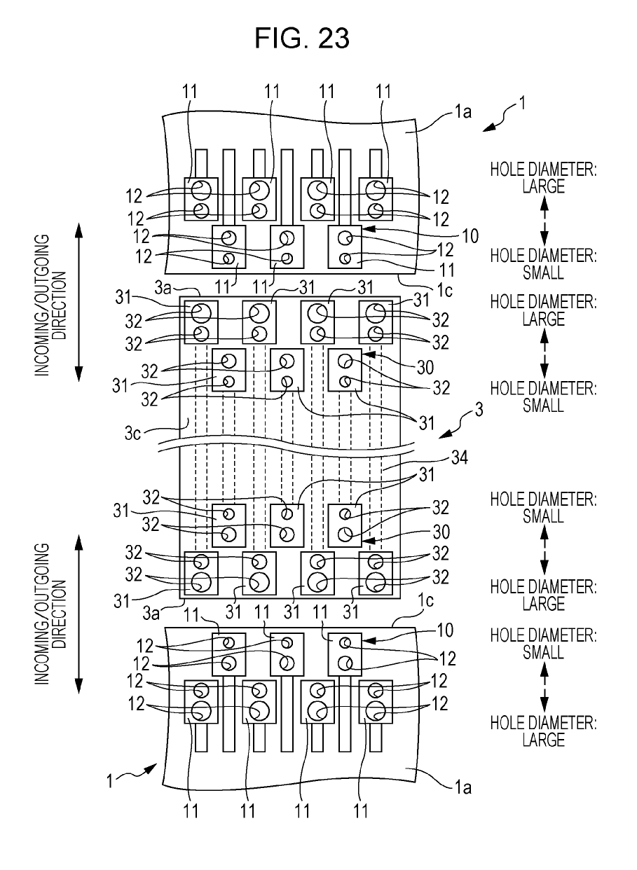

FIG. 23 is a diagram for describing a detailed structure of the RPC joint parts 10 and FPC joint parts 30 according to a third modification example. In the third modification example, the plurality of FPC lands 31 are arranged in a staggered manner on the relay FPC 3 along the end face 3a, and the plurality of RPC lands 11 are arranged in a staggered manner on the rigid printed circuit board 1 along the end face is so as to correspond to the arrangement pattern of the FPC lands 31. When the plurality of FPC lands 31 are arranged on the relay FPC 3, the FPC lands 31 are arranged in the staggered manner along the width direction of the relay FPC 3 as in the present modification example, thereby effectively utilizing the space of the relay FPC 3 and arranging more FPC lands 31. Similarly, the RPC land 11 are arranged in the staggered manner on the rigid printed circuit board 1 so as to correspond to the arrangement pattern of the FPC lands 31, thereby effectively utilizing the space of the rigid printed circuit board 1 and arranging more RPC lands 11.

Also, in the third modification example, of the solder drawing holes 32 arranged on each FPC land 31 in the relay FPC 3, the solder drawing hole 32 with a smaller separation dimension from the end face 3a has a larger hole diameter. In the rigid printed circuit board 1, the solder filling hole 12 with a larger separation dimension from the end face is has a larger hole diameter. With this, effects similar to those of the second modification example are provided. That is, since the solder filling hole 12 corresponding to the solder drawing hole 32 with a smaller separation dimension from the end face 3a of the relay FPC 3 has a larger diameter, it is possible to more reliably correct the mount position even on the end face 3a susceptible to the influence of heat warping at the time of reflow heating. Furthermore, the drawing capacity of the superfluous cream solder 4A is larger at a portion closer to the end face 3a of the relay FPC 3. Therefore, a short circuit between adjacent FPC lands 31 or between adjacent RPC lands 11 may be favorably suppressed.

Still further, in the third modification example, of the solder drawing holes 32 in the relay FPC 3, the solder drawing hole 32 with a smaller separation dimension from the end face 3a is formed to have a larger hole diameter. For example, in an example depicted in FIG. 23, compared to the FPC land 31 with a farther distance from the end face 3a, the solder drawing hole 32 formed in the FPC land 31 arranged at a position closer to the end face 3a has a larger diameter. Also, of the solder filling holes 12 in the rigid printed circuit board 1, the solder filling hole 12 with a larger separation dimension from the end face 1c is formed to have a larger hole diameter. In the example depicted in FIG. 23, compared to the RPC land 11 with a distance closer to the end face 1c, the solder filling hole 12 formed in the RPC land 11 arranged at a position farther to the end face is has a larger diameter. According to this, of the solder filling holes 12 in the rigid printed circuit board 1, the solder filling hole 12 corresponding to the solder drawing hole 32 with a smaller separation dimension from the end face 3a in the relay FPC 3 is formed to have a larger diameter. As a result, even if the heat warping amount on the end face 3a side of the relay FPC 3 is increased at the time of reflow heating, the mount position of the relay FPC 3 is more reliably corrected. Also in the relay FPC 3, since the capacity of the solder drawing hole 32 accommodating the superfluous cream solder 4A is larger at a portion closer to the end face 3a, a short circuit between adjacent FPC lands 31 or between adjacent RPC lands 11 may be favorably suppressed.

While the embodiment and the modification examples of the printed circuit board solder mounting method and solder mount structure have been described above, the embodiment and the modification examples are not restrictive. It is obvious to persons skilled in the art that the embodiment and the modification examples may be variously changed, improved, or combined.

For example, in the embodiment and the modification examples, the solder filling holes 12 to be filled with the cream solder 4A in the solder filling process are formed on the rigid printed circuit board 1. Alternatively, the solder filling holes 12 may be provided so as to be open in the planar region of each FPC land 31 in the relay FPC 3. The solder drawing holes 32 may be provided so as to be open in the planar region of each RPC land 11 in the rigid printed circuit board 1. That is, the solder filling holes 12 and the solder drawing holes 32 in the present embodiment may be arranged so as to be interchanged with each other.

Also in this case, it is preferable that the solder wettability of the solder drawing hole 32 be relatively higher than the solder wettability of the solder filling hole 12. For example, while each solder drawing hole 32 may be formed as a through hole by plating on the inner surface, each solder filling hole 12 may be formed as non-through hole. In this modification example, the relay FPC 3 is preferably mounted by first filling the solder filling holes 12 provided in the relay FPC 3 with the cream solder 4A, mounting the relay FPC 3 on the rigid printed circuit board 1, and then performing reflow heating.

According to the above, at the time of reflow heating, the cream solder 4A may be moved by ascending from the solder filling hole 12 formed in the relay FPC 3 to the solder drawing hole 32 formed in the rigid printed circuit board 1. Here, even if the mount position of the relay FPC 3 is shifted from the normal position or the FPC lands 31 are departed from the RPC lands 11 in the height direction due to heat warping, the self alignment effect may be exerted by surface tension of the cream solder 4A. As a result, the influence of the mount error and heat warping of the relay FPC 3 may be resolved, and solder reach failure may be suitably suppressed. In the present modification example, the relay FPC 3 is an example of the first printed circuit board, and the rigid printed circuit board 1 is an example of the second printed circuit board.

In the embodiment, an example of application when the relay flexible printed circuit board is mounted on the rigid printed circuit board 1 is described. However, this use purpose is not restrictive. For example, the solder mount structure (mounting method) described in the present embodiment may be suitably applied when a flexible printed circuit board (FPC) for use as a function module having any of various semiconductor devices, microchips, and so on mounted thereon is mounted on a printed circuit board. Also, the solder mount structure (mounting method) described in the present embodiment may be applied not only to solder mounting of an FPC on a rigid printed circuit board but also to solder mounting of rigid printed circuit boards and solder mounting of FPCs. That is, by forming the solder filling holes 12 in one of paired rigid printed circuit boards (or FPCs) and forming the solder drawing holes 32 in the other, a mount error occurring in the mounting process may be suitably resolved by self alignment at the time of reflow heating.

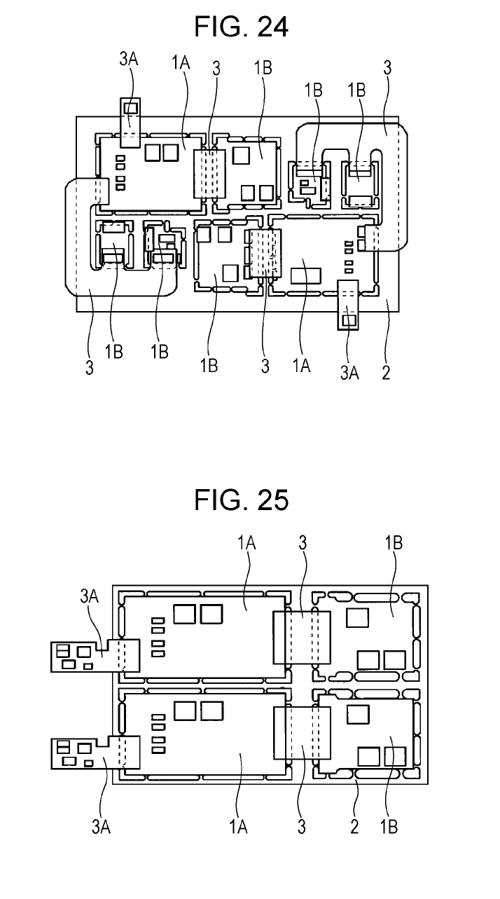

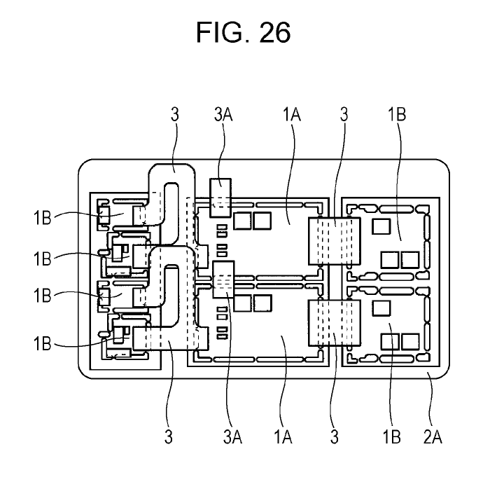

FIGS. 24 to 26 exemplarily illustrate variations of a printed circuit board unit to which the printed circuit board solder mounting method and solder mount structure according to the present embodiment. In FIGS. 24 to 26, 1A denotes a main board, and 1B denotes a sub-board. 3A denotes the FPC as a function module having semiconductor devices mounted thereon. In examples depicted in FIGS. 24 to 26, a plurality of main boards 1A and sub-boards 1B are provided on one large printed circuit board 2, and each of the main boards 1A and the sub-boards 1B has an outer shape provided with V-shaped grooves or perforated parts. After the relay FPCs 3 and FPCs 3A are mounted on the main boards 1A and the sub-boards 1B, the main boards 1A and the sub-boards 1B are cut by a mounted board cutter (not depicted) along the V-shaped grooves or perforated parts, thereby obtaining a printed circuit board unit. As depicted in FIG. 26, the main boards 1A, the sub-boards 1B, and so on may be fixed to a printed circuit board fixing palette 2A for mounting the relay FPCs 3, the FPCs 3A, and so on.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A printed circuit board solder mounting method of solder-jointing a first land formed on a first printed circuit board and a second land formed on a second printed circuit board together, comprising:
filling a solder filling hole with cream solder, the solder filling hole provided so as to be open in a planar region of the first land;
arranging a solder drawing hole so that the solder drawing hole and the solder filling hole face each other, the solder drawing hole being formed so as to be open in a planar region of the second region, having a center position to be superposed on a center position of the solder filling hole, and having a solder wettability higher than a solder wettability of the solder filling hole;
melting the cream solder in the solder filling hole by reflow heating and causing at least part of the cream solder to ascend to the solder drawing hole facing the solder filling hole; and
jointing the first land and the second land together by solidifying the cream solder interposed between the first land and the second land.

2. The printed circuit board solder mounting method according to claim 1, wherein
the solder drawing hole is formed as a through hole penetrating through the second printed circuit board, and
a third land is formed at an edge of the solder drawing hole on a main surface of the second printed circuit board opposite to the second land, the third land for causing the cream solder moved to the solder drawing hole to ascend.

3. The printed circuit board solder mounting method according to claim 1, wherein
the solder filling hole is formed by causing a resin base material of the first printed circuit board to be exposed without being processed to an inner surface of a hole formed in the first printed circuit board, and
the solder drawing hole is formed by coating an inner surface of a hole formed in the second printed circuit board with a metal film.

4. The printed circuit board solder mounting method according to claim 1, wherein
a plurality of the solder filling holes are arranged in the planar region of the first land in the first printed circuit board, and
a plurality of the solder drawing holes are arranged in the planar region of the second land in the second printed circuit board.

5. The printed circuit board solder mounting method according to claim 1, wherein
a corresponding plurality of the first lands and the second lands are formed on the first printed circuit board and the second printed circuit board, respectively,
at least one or more of the solder filling holes are arranged in the planar region of each of the first lands, and
at least one or more of the solder drawing holes are arranged in the planar region of each of the second lands.

6. The printed circuit board solder mounting method according to claim 1, wherein
the first printed circuit board is a rigid printed circuit board, and
the second printed circuit board is a flexible printed circuit board.

7. The printed circuit board solder mounting method according to claim 6, wherein
the second land is formed near an end face of the flexible printed circuit board,
the plurality of solder drawing holes are arranged so as to be aligned in the planar region of the second land along a direction orthogonal to the end face, and
the plurality of solder filling holes are arranged so as to be aligned in the planar region of the first land in the rigid printed circuit board at positions corresponding to the plurality of solder drawing holes in the flexible printed circuit board.

8. The printed circuit board solder mounting method according to claim 7, wherein,
of the plurality of solder filling holes arranged in the planar region of the first land in the rigid printed circuit board, a solder filling hole corresponding to a solder drawing hole with a smaller separation dimension from the end face in the flexible printed circuit board is formed to have a larger diameter.

9. The printed circuit board solder mounting method according to claim 8, wherein,
of the plurality of solder drawing holes arranged in the planar region of the second land in the flexible printed circuit board, a solder drawing hole with a smaller separation dimension from the end face in the flexible printed circuit board is formed to have a larger diameter.

10. The printed circuit board solder mounting method according to claim 6, wherein
a plurality of the second lands are arranged in a staggered manner along the end face of the flexible printed circuit board, and a plurality of the first lands are arranged in a staggered manner on the rigid printed circuit board so as to correspond to an arrangement pattern of the second lands.

11. The printed circuit board solder mounting method according to claim 10, wherein,
of the plurality of solder filling holes formed in the rigid printed circuit board, a solder filling hole corresponding to a solder drawing hole with a smaller separation dimension from the end face in the flexible printed circuit board is formed to have a larger diameter.

12. The printed circuit board solder mounting method according to claim 11, wherein,
of the plurality of solder drawing holes formed in the flexible printed circuit board, a solder drawing hole with a smaller separation dimension from the end face in the flexible printed circuit board is formed to have a larger diameter.

13. The printed circuit board solder mounting method according to claim 1, wherein
the solder filling hole and the solder drawing hole corresponding to each other are formed to have a same diameter.

14. A printed circuit board solder mount structure comprising:
a solder jointing material to solder-joint a first land formed on a first printed circuit board and a second land formed on a second printed circuit board together;
a solder filling hole to be open in a planar region of the first land and to be filled with cream solder that forms the solder jointing material; and
a solder drawing hole to be open in a planar region of the second land and to be arranged to face the solder filling hole so that a center position of the solder drawing hole is superposed on a center position of the solder filling hole; wherein
the solder drawing hole has a solder wettability higher than a solder wettability of the solder filling hole, and
at reflow heating, at least part of the cream solder filled in the solder filling hole is melted to ascend to the solder drawing hole facing the solder filling hole, and the cream solder interposed between the first land and the second land is solidified to joint the first land and the second land.
